(19) United States
(12) Patent Application Publication
(10) Pub. No.: US 2020/0243413 A1
(43) Pub. Date: Jul. 30, 2020

(54) METHODS, DEVICES, AND SYSTEMS FOR SUBSTRATE TEMPERATURE MEASUREMENTS

(71) Applicant: Avago Technologies International Sales Pte. Limited, Singapore (SG)

(72) Inventors: Milos Davidovic, Vienna (AT); Mladen Mitrovic, Vienna (AT); Wolfgang Gaberl, Vienna (AT)

(21) Appl. No.: 16/262,237

(22) Filed: Jan. 30, 2019

(51) Int. Cl. H01L 23/34; H01L 27/144; H01L 23/522; G01K 7/18; G01J 1/44

(52) U.S. Cl. CPC H01L 23/34; H01L 27/1446; H01L 23/5228; G01J 2001/442; G01K 7/18; G01J 1/44; H01L 23/5226

(57) ABSTRACT

A semiconductor substrate includes a first surface including an optical detection section that converts optical signals into electrical signals. The semiconductor substrate includes a second surface opposite the first surface and including one or more first contacts electrically connected to the optical detection section to communicate the electrical signals from the optical detection section to another substrate. The semiconductor substrate includes a temperature sensing element that includes a resistive structure on at least the first surface or the second surface. The resistive structure has a resistance that varies with temperature.

### FIELD OF THE DISCLOSURE

Example embodiments are generally directed toward methods, devices, and systems for temperature measurements of substrates and/or components on substrates.

### BACKGROUND

Temperature measurements of a substrate and/or of components on a substrate are desired for many applications in which temperature may have an effect on signals sensed and/or output by components on and/or within the substrate.

### BRIEF DESCRIPTION OF THE DRAWINGS

Inventive concepts are described in conjunction with the appended figures, which are not necessarily drawn to scale:

FIG. 1 illustrates a system according to at least one example embodiment;

FIG. 2A illustrates an example first surface of the substrate from FIG. 1 according to at least one example embodiment;

FIG. 2B illustrates an example second surface of the substrate form FIG. 1 according to at least one example embodiment;

FIG. 3A illustrates an exploded view of the package in FIG. 1 according to at least one example embodiment;

FIG. 3B illustrates cross-sectional views of an assembled package from FIG. 3A according to at least one example embodiment;

FIG. 4A illustrates an example structure of the sensing circuit in FIG. 3A according to at least one example embodiment;

FIG. 4B illustrates another example structure of the sensing circuit in FIG. 3A according to at least one example embodiment;

FIG. 5 illustrates a package according to at least one example embodiment;

FIG. 6 illustrates a package according to at least one example embodiment; and

FIG. 7 illustrates a package according to at least one example embodiment.

### DETAILED DESCRIPTION

Example embodiments relate to methods, devices, and systems for substrate temperature measurements. For example, in optical sensing applications, such as single photon detection applications using silicon photomultiplier (SiPM) detectors, it may be desired to obtain temperature measurements of the substrate on which the detectors are formed.

As such, example embodiments relate to measuring the temperature of a substrate and/or of components on the substrate, for example, in single photon detection applications using Silicon PhotoMultiplier (SiPM) detectors within positron emission tomography (PET) scanner devices. The SiPMs have temperature dependent gain, which can be compensated for by applying different bias voltages to the SiPM terminals, namely the anode and/or cathode. Thus, in order to keep the gain constant and achieve reliable system operation, it is desired to measure the SIPMs' die or substrate temperature and adjust the bias voltage accordingly. Related art solutions lack a temperature sensing element that is monolithically integrated with the substrate of the SiPMs.

Example embodiments propose to use a linear metal structure as a temperature sensing element. The metal structure has a resistance and the resistance is temperature dependent. Using metal as the resistor provides at least the following advantages: 1) metals, such are Al or Cu, are widely available and easy to incorporate into a process flow; 2) metal has a stable linear temperature coefficient which may be in the range of about 0.003 to about 0.005/° C., depending on the material/alloy used for metallization; and 3) metal may be scattered over the area of interest to enable homogenous measurements, rather than be limited to pointwise measurements.

The ensuing description provides example embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

Various aspects of example embodiments will be described herein with reference to drawings that are schematic illustrations of idealized configurations. As such, variations from the shapes of the illustrations as a result, for example, manufacturing techniques and/or tolerances, are to be expected. Thus, the various aspects of example embodiments presented throughout this document should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of example embodiments.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” or “established” on another element, it can be grown, deposited, etched, attached, connected, coupled, or otherwise prepared or fabricated on the other element or an intervening element.

Furthermore, relative terms, such as “lower” or “bottom” and “upper” or “top” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can, therefore, encompass both an orientation of “lower” and “upper” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

The phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “include,” “includes,” ‘including,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

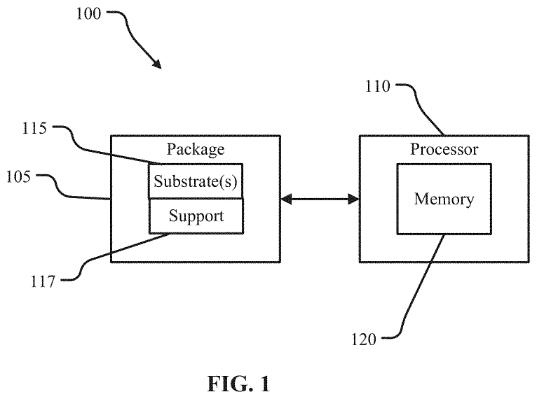

FIG. 1 illustrates a system 100 according to at least one example embodiment. The system 100 includes a package 105 coupled to a processor 110. The package 105 may include one or more substrates 115 having electrical, optical, and/or mechanical components that generate electrical signals to be processed by the processor 110. For example, the substrate 115 may be a semiconductor substrate (e.g., silicon) and may include an optical detector with a plurality of optical elements that convert detected light into electrical signals for processing by the signal processor 110. In at least one example embodiment, the optical elements include silicon photomultiplier (SiPM) detectors in the form of single-photon avalanche diodes (SPAD) for use in positron emission tomography (PET) systems. As discussed in more detail below, the substrate 115 may include a temperature sensing element for monitoring a temperature of the substrate 115 and/or other components mounted on and/or formed within the substrate 115. Here, it should be understood that example embodiments are not limited to substrates having optical detectors, and that example embodiments may be useful for any application that desires temperature monitoring of a substrate having electrical, optical, and/or mechanical components.

The package 105 may further include a support or support substrate 117 attached to and supporting the substrate 115. For example, the support 117 may be another substrate, such as a printed circuit board (PCB), that makes electrical connection with the substrate 115 and the processor 110 to pass electrical signals from the substrate 115 to the processor 110.

The processor 110 may correspond to one or many computer processing devices. For instance, the processor 110 may be provided as a Field Programmable Gate Array (FPGA), an Application-Specific Integrated Circuit (ASIC), any other type of Integrated Circuit (IC) chip, a collection of IC chips, a microcontroller, a collection of microcontrollers, or the like. As a more specific example, the processor 110 may be provided as a microprocessor, Central Processing Unit (CPU), or plurality of microprocessors that are configured to execute instructions sets stored in a memory 120. Upon executing the instruction sets stored in memory 120, the processor 110 processes signals from the package 105 to provide outputs indicative of the signals received from the package 105.

The memory 120 may include any type of computer memory device or collection of computer memory devices. The memory 120 may be volatile or non-volatile in nature and, in some embodiments, may include a plurality of different memory devices. Non-limiting examples of memory 120 include Random Access Memory (RAM), Read Only Memory (ROM), flash memory, Electronically-Erasable Programmable ROM (EEPROM), Dynamic RAM (DRAM), etc. The memory 120 may be configured to store the instruction sets for the processor 110 in addition to temporarily storing data for the processor 110 to execute various types of routines or functions.

The package 105 and the processor 110 may be coupled to one another via one or more known wired connections and/or wireless connections. Although the system 100 illustrates the package 105 and the processor 110 being separate from one another, it should be understood that the processor 110 may be integrated with the package 105, for example, on the substrate(s) 115 and/or support 117.

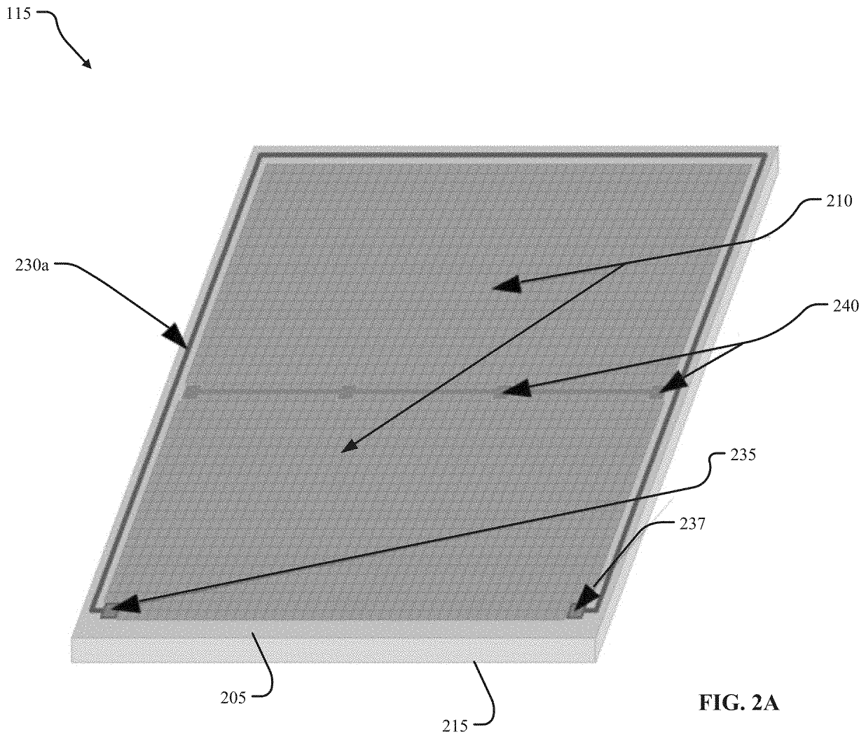

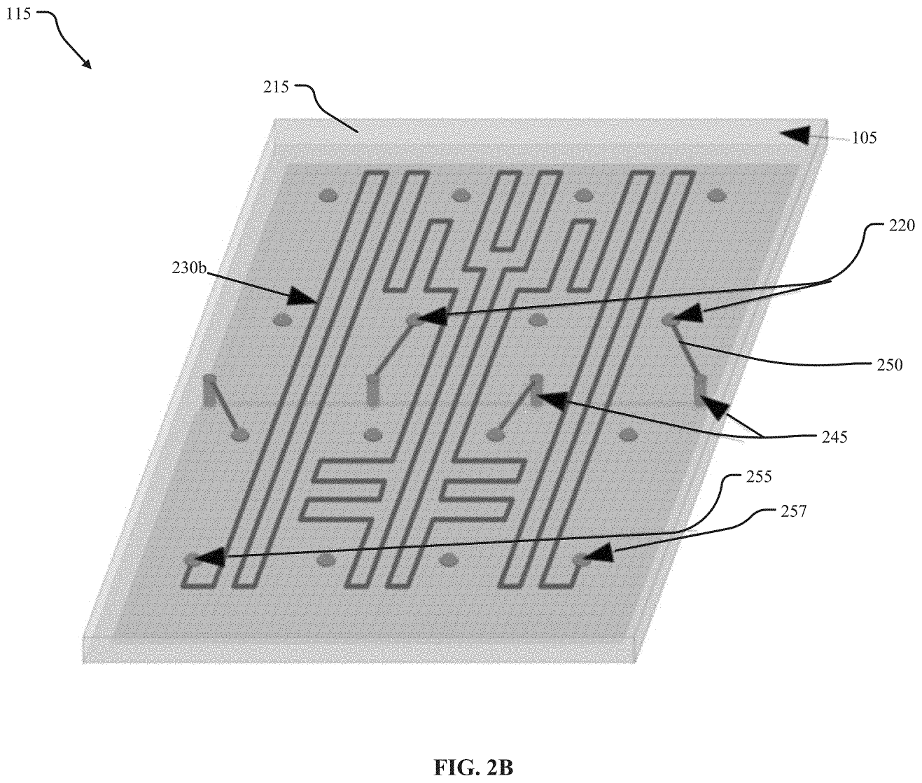

FIGS. 2A and 2B illustrate examples for the substrate 115 from FIG. 1. For example, FIG. 2A illustrates an example first surface of the substrate 115 while FIG. 2B illustrates an example second surface of the substrate 115, where the second surface is opposite the first surface. With reference to FIGS. 2A and 2B, the substrate 115 may be a semiconductor substrate comprised of silicon or other suitable semiconductor. The substrate 115 may include a first surface 205 including an optical detection section 210 that converts optical signals (e.g., x-rays, visible light, ultra-violet light, infrared, etc.) into electrical signals. For example, the optical detection section includes a plurality of optical elements (e.g., photodiodes, SPADs, light sensing transistors, etc.) arranged in a matrix and that convert incident electromagnetic radiation (visible light, infrared light, x-rays, gamma rays, etc.) into electrical charge.

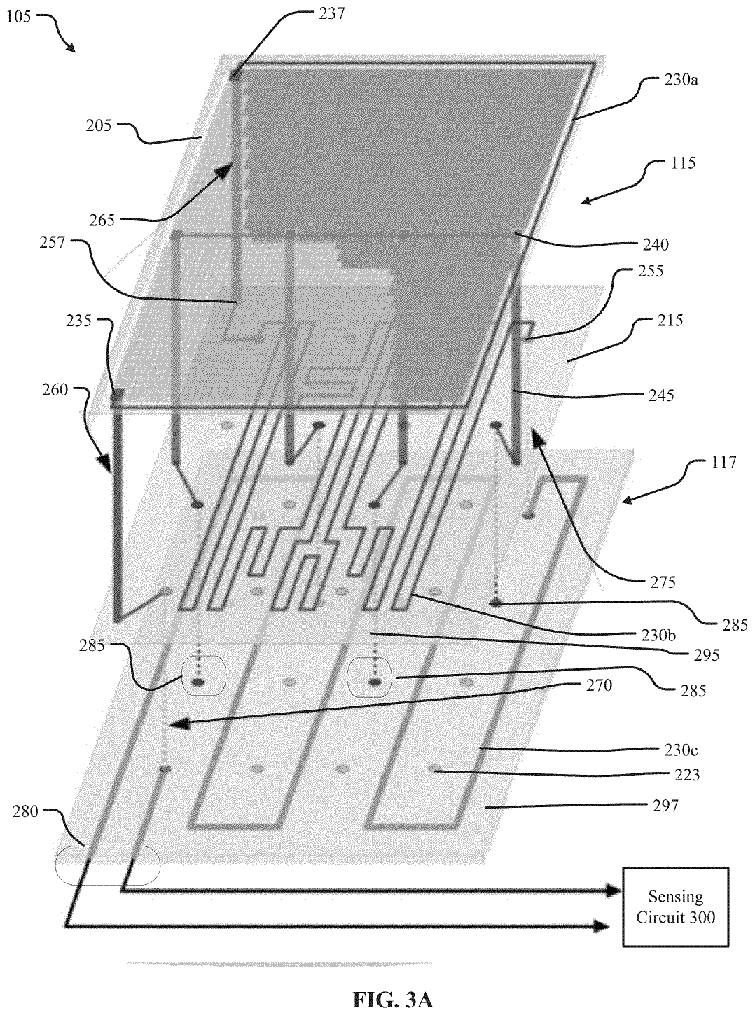

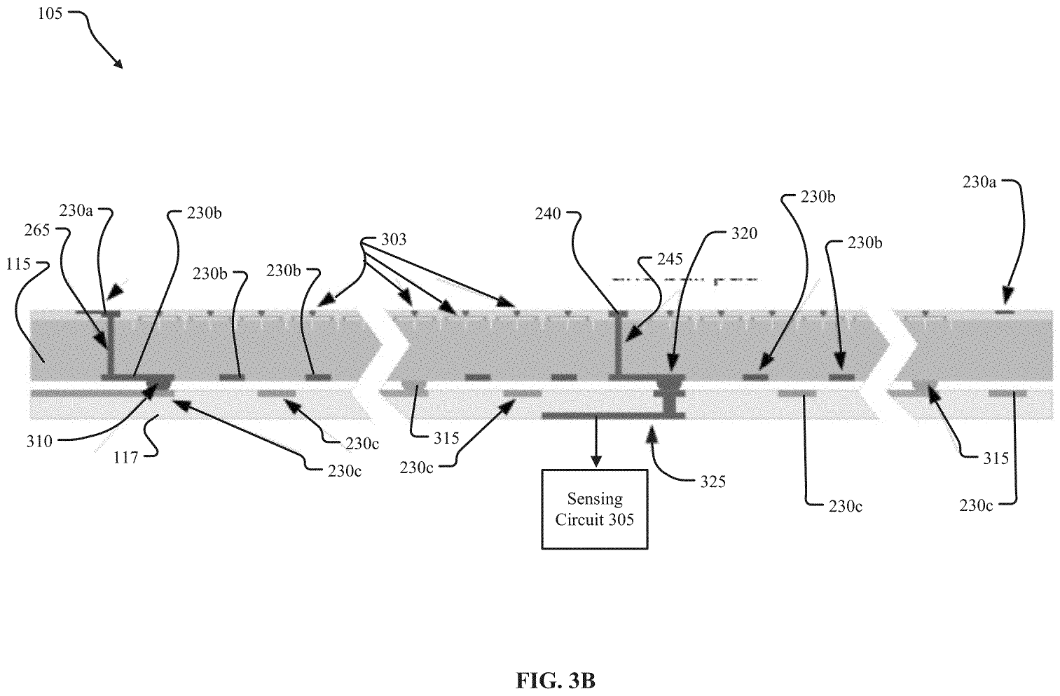

The substrate 115 includes a second surface 215 opposite the first surface 205 and including one or more first contacts 220 electrically connected to the optical detection section 210 to communicate the electrical signals from the optical detection section 210 to another substrate, for example the support substrate 117 (see FIG. 3A, for example). FIG. 2B illustrates a plurality of contacts 220 arranged in a desired pattern, such as a grid.

The substrate 115 includes a temperature sensing element 230. The temperature sensing element 230 may comprise a resistive structure on at least the first surface 205 or the second surface 215. For example, in at least one example embodiment, the first surface 205 includes a first portion of the resistive structure 230a, which is on the first surface 205 at a periphery of the optical detection section 210. As shown in FIG. 2A, the resistive structure 230a is at the periphery of the optical detection section 210 around at least three sides of the optical detection section 210. The resistive structure 230a may include ends 235/237 that are electrically connected to respective vias that extend from the first surface 205 to the second surface 215 (see FIG. 3A, for example). However, example embodiments are not limited thereto, and the first portion of the resistive structure 230a may be formed at more or fewer sides of the optical detection section 210. For example, if desired, the resistive structure 230a may extend along the side of the optical detection section 210 that is illustrated as not being occupied by the resistive structure 230a.

In at least one example embodiment, as depicted in FIG. 2B, a second portion of the resistive structure 230b is on the second surface 215 and overlaps the optical detection section 210 in a plan view. As shown, the resistive structure 230b may be sinuous and have line symmetry. The resistive structure 230b may include portions that pass between various ones of the contacts 220. For example, when the one or more first contacts 220 includes a plurality of first contacts 220 arranged in a desired pattern on the second surface, the sinuous resistive structure 230b may wind between ones of the plurality of first contacts 220.

Here, it should be understood that the substrate 115 may include the resistive structure 230a, the resistive structure 230b, or both, according to design preferences.

The resistive structure 230 may have a resistance that varies with temperature to enable temperature measurements via resistance measurements. According to at least one example embodiment, the resistive structure comprises a metal, such as aluminum and/or copper, or other suitable conductor having a substantially linear temperature coefficient.

With reference to FIGS. 2A and 2B, the substrate 115 further includes one or more second contacts 240 on the first surface 205 and electrically connected to the optical detection section 210. The substrate 115 may further include one or more vias 245 formed through the substrate 115 and that electrically connect the one or more second contacts 240 to the one or more first contacts 220 to pass the electrical signals generated by the optical detection section 210 to the support substrate 117. As shown in FIG. 2B, wirings 250 may be included on the second surface 215 to connect the vias 245 to the contacts 220. As also shown, not all contacts 220 include electrical connections to the contacts 240. For example, some contacts 220 may be dummy contacts used for bonding to the support 117, for spacing the substrate 115 from the support 117, etc. In some embodiments, some contacts 220 provide an electrical connection to the substrate 115 itself, thus forming a second terminal of the optical detection section 210 (first terminal being the set of second contacts 240).

FIGS. 3A and 3B illustrate various views of the package 105 according to at least one example embodiment, including the substrate 115 and the support 117 (or support substrate 117). In more detail, FIG. 3A illustrates an exploded view of the package 105 according to at least one example embodiment while FIG. 3B illustrates cross-sectional views of an assembled package 105 in FIG. 3A at different locations. For the sake of explanation, the second surface 215 of the substrate 115 in FIG. 3A is shown as being exploded from the rest of the substrate 115.

FIGS. 3A and 3B illustrate an example where the substrate 115 includes both resistive structures 230a and 230b. As illustrated in FIG. 3A, the right contact of the terminal 280 may be connected on the third surface 297 with a metal line (which could be said to belong to the resistive structure 230c) to a bottom left red unmarked contact then with bump connection 270 to the second surface 215. This connection continues through a contact on the second surface with another metal line. Then, the metal line is connected with via 260, which is connected to the contact 235 of the resistive structure 230a on the first surface 205.

The connection continues to the second contact 237 using path 230a and then to the second surface 215 with via 265, which is connected to contact 257. From via 257, the connection continues to the contact 257 and then to via 230b to the top right contact. This connection then continues with a bump 275 down to the third surface 297, to the top-right unmarked contact and finally to connection 230c to the left contact of the terminal 280.

The substrate 115 may include a second via 265 that extends from the first surface 205 to the second surface 215 to electrically connect a second part or end 237 of the first portion of the resistive structure 230a to a second part 257 of the second portion of the resistive structure 230b (see FIG. 3A).

As shown in FIG. 3A, the substrate 115 includes the first portion of the resistive structure 230a on the first surface 205 and the second portion of the resistive structure 230b on the second surface 215. Package 105 further includes the support 117 (or support substrate 117). The support substrate 117 may include a third portion of the temperature sensing element 230 as a third resistive structure 230c on a surface 297 of the support substrate 117. As shown, the second portion of the resistive structure 230b and the third portion of the resistive structure 230c overlap the plurality of optical elements in the optical detection section 210 in a plan view.

Upon assembly of the package 105, surface 215 is attached to the surface 297 by, for example, bonding contacts 220 to contacts 223. In at least one example embodiment, the contacts 220 and 223 are bonded to one another with solder bumps or other suitable bonding method. Solder bump connections 270 and 275 are shown as dotted lines in FIG. 3A for clarity. However, more or fewer solder bump connections may be included according to design preferences. In at least one example embodiment, the second portion 230b and the third portion 230c of the temperature sensing element 230 are sinuous and at least partially overlap one another. In this case, areas of the second portion 230b and the third portion 230c that overlap one another are physically separated by a space or isolation material between the second surface 215 and the third surface 297.

In at least one other example embodiment, the portions 230b or 230c take on a same or similar pattern as portion 230a so that the portions 230b and 230c do not overlap.

Here, it should be appreciated that substrates 115 and 117 may be bonded to one another so that the resistive structure 230b and the resistive structure 230c do not make electrical contact. This isolation may be accomplished as a result of non-overlapping patterns of the structures 230b/230c, an isolation material between the structures 230b/230c, and/or as a result of the solder bumps that create a gap between the substrates 115/117.

The support substrate 117 may further include a second set of terminals 285 electrically connected to the plurality of optical elements of the optical detection section 210. A number of the second set of terminals 285 vary according to design preferences, for example, according to how many detection contacts 240 are used.

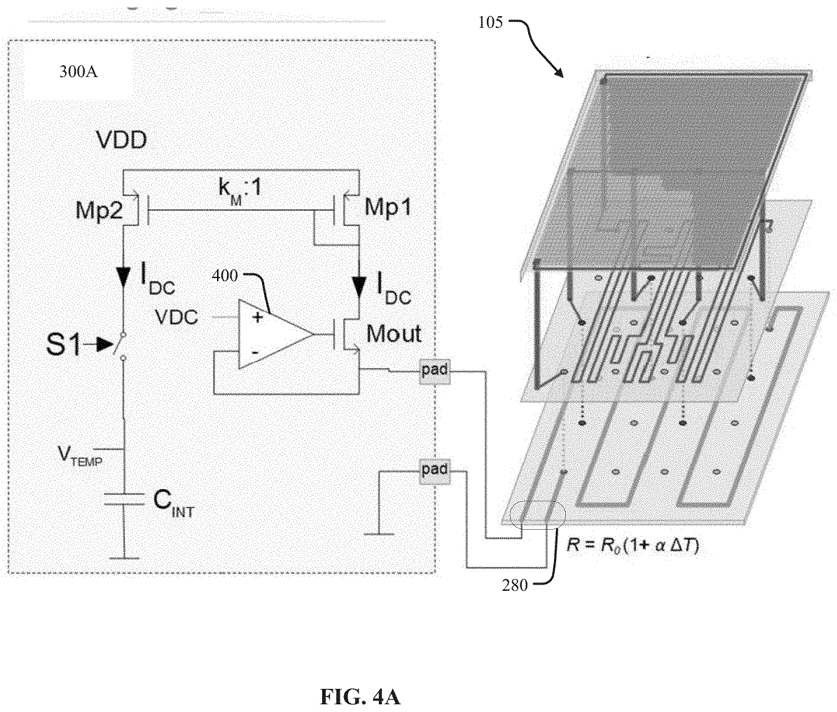

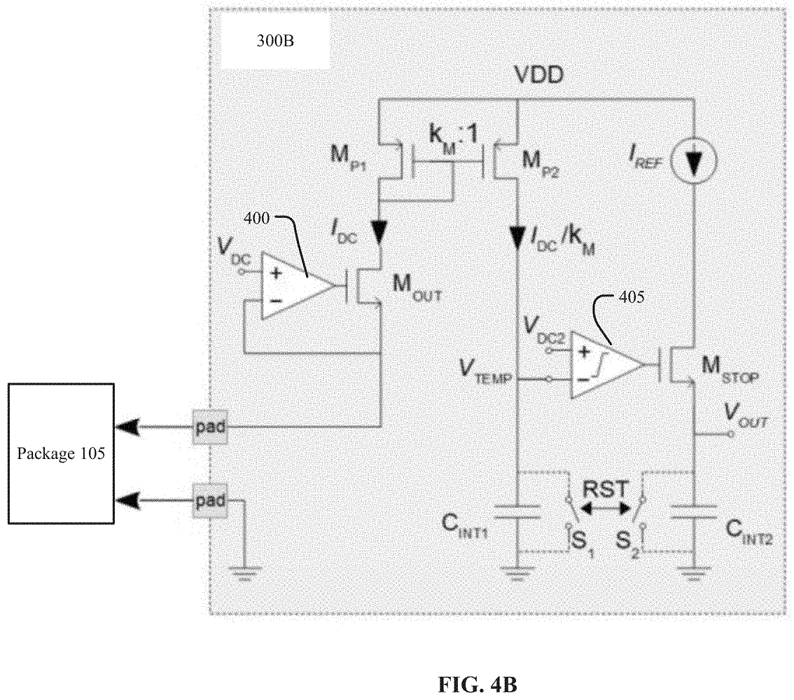

In at least one example embodiment, the support substrate 117 includes a first set of terminals 280 electrically connected to the temperature sensing element 230 via the third portion of the resistive structure 230c. The first set of terminals 280 are connectable (e.g., via wires) to a sensing circuit 300 for sensing a resistance of the resistive structures 230a 230b, and 230c. The sensing circuit 300 is shown in more detail in FIGS. 4A and 4B. In at least one example embodiment, the sensing circuit 300 is part of the package 105 and/or the processor 110.

Resistive structures 230a, 230b, and 230c may have widths of about 3 micrometers to about 100 micrometers, thicknesses of about 1 micrometer, and may be formed according to any known process for depositing metal on a substrate. However, example embodiments are not limited thereto, and the dimensions and manner of formation for the resistive structures may vary according to design preferences. For example, depending on the technology node, the minimum width can be in the 100 nm range, and thickness also can be as low as 100-200 nm. Moreover, the dimensions may also depend on the type of fabrication. If it is an integrated circuit design (which is used for SiPM fabrication) then it is the nm order of magnitude, but can be μm too. Utilization of a PCB design (e.g., substrate 117) can be on the order of some tens of μm.

FIG. 3B illustrates various cross-sectional views of an assembled package 105 in FIG. 3A. For brevity, only those elements included in FIG. 3B but not discussed above will be described below.

As shown in FIG. 3B, the optical detection section 210 includes a plurality of optical elements 303 which may include a metal grid with corresponding poly-Si connections to a photodetector, or other structure known in the art that is suitable for SiPMs. In FIG. 3B, solder bumps 310, 315, and 320 are shown to illustrate the bonding the substrate 115 to the support substrate 117. Bump 310 provides an electrical connection between the resistive structure 230b and the resistive structure 230c while bump 320 provides an electrical connection between a contact 240 and wiring 325. FIG. 3B further illustrates a sensing circuit 305 coupled to the wiring 325. The sensing circuit 305 may process the electrical signals of the optical elements 303 passed through the wiring 325. Accordingly, the sensing circuit 305 may include any known circuitry for accumulating and outputting charge collected by the optical elements 303 based on incident light.

The sensing circuits 300 and 305 may be included as part of the package 105 and/or as part of the processor 110 according to design preferences.

As noted above, the sensing circuit 300 is capable of detecting resistance changes. One challenge of using a metal resistive structure 230 as the temperature sensing element is the low sheet resistance of a metal layer. Depending on the deposited thickness of the resistance structures 230a, 230b, and/or 230c, the sheet resistance may be from about 0.003Ω/□ to about 0.1 Ω/□.

An initial resistance of the temperature sensing element 230 may be in the range of about 10Ω to about 10 kΩ. For the sake of explanation, consider the following example. Assume a resistive structure 230 with a resistance R0 of 100Ω at reference temperature T0, with a temperature coefficient α=0.003/° C. The metal resistance R as a function of temperature T can be expressed as R_{(T)}=R₀ (1+α(T−T₀))=R₀ (1+α·ΔT), where R₀ is the resistance in Ω at some reference temperature T₀ expressed in ° C. (e.g., 0° C., room temperature, etc.), and α is the temperature coefficient expressed in 1/° C. If detecting a temperature range of about 50° C., it is desired to have a sensing circuit 300 that can sense the change of resistance in the range of 15% in case of the given coefficient α=0.003/° C. Furthermore, if we target 0.1° C. accuracy, the sensing circuit 300 should resolve a 0.03% resistance change.

FIG. 4A illustrates an example structure of the sensing circuit in FIG. 3A according to at least one example embodiment that can achieve the above desired sensing characteristics. As shown, the sensing circuit 300A may include two contact pads or other type of inputs for making electrical connection to the first set of terminals 280. The sensing circuit 300A may include transistors Mp1, Mp2, M_{OUT}, a switch S1, an amplifier 400, and a capacitance C_{INT} connected to one another as shown. The circuit 300A may include inputs for supply voltage VDD, amplifier voltage VDC, and the switch S1.

The sensing circuit 300A may be referred to as a single-slope or dual slope integrating analog-to-digital (ADC).

The sensing circuit 300A may detect resistance changes, which are in sub-percent range, even if only a low-resistance resistor is available as the temperature sensing element 230. With reference to FIG. 4A, is should be understood that the voltage across the resistive structure 230 is regulated to the V_{DC} voltage by means of the amplifier 400 and output transistor M_{OUT}. The current I_{DC}, which is generated across the resistive structure 230, can be expressed as I_{DC(T)}=V_{DC}/R_{(T)}=V_{DC}/(R₀(1+α·ΔT)). The input current I_{DC} is scaled by a factor 1:k_{M}, which may be adjustable, and mirrored to the MOSFET MP2, flowing to the integrating capacitor C_{INT}. The voltage V_{TEMP} after the given integration time τ can be expressed as:

V_{TEMP(T)}=(I_{DC}·τ)/(k_{M}·C_{INT})=(V_{DC}·τ)/(k_{M}·C_{INT}·R_{(T)})

With regards to the temperature T, all of the parameters apart from R_{(T)} in the equation are constants so that the voltage V_{TEMP(T)} has pure temperature dependence.

Here, switch S1 controls an integration time for V_{TEMP}. For example, switch S1 is controlled (e.g., by a control signal from the processor 110) to be closed when the sensing circuit 300A is integrating. Then, switch S1 is controlled to be open when V_{TEMP} is desired to be read out (e.g., by the processor 110). The processor 110 may interpret the voltage V_{TEMP} as a temperature value by matching a value of V_{TEMP} to a temperature in a lookup table (LUT), for example, where the LUT contains a range of values for V_{TEMP} each having an associated temperature value (e.g., in ° C.). The temperature value may be used to adjust bias voltages applied to the SiPMs of the optical detection section 210.

FIG. 4B illustrates an example structure of the sensing circuit in FIG. 3A according to at least one example embodiment that can achieve the above desired sensing characteristics with improved temperature linearity. FIG. 4B includes some of the same elements as FIG. 4A, and as such, a description of these elements will not be repeated. The sensing circuit 300B may be referred to as a single-slope or dual slope integrator used in high precision analog-to-digital converters (ADC).

In FIG. 4B, the comparator 405 detects when the voltage V_{TEMP} becomes larger than a reference voltage V_{DC2}. The comparator 405 output is used to switch off the transistor M_{STOP} in the output branch, thus controlling the time period τ during which the integration of the reference current I_{REF} onto the capacitor C_{INT2} takes place. Bearing this in mind, the voltage V_{TEMP} after the given integration time τ can be expressed as:

V_{TEMP(T)}=(I_{DC}·τ)/(k_{M}·C_{INT1})=(V_{DC}·τ)/(k_{M}·C_{INT1}·R_{(T)}).

This gives the expression for T, for which V_{TEM(T)} becomes equal to V_{DC2}: τ=V_{DC2}((k_{M}·C_{INT1})/V_{DC})·R_{(T)}=k_{M}·k_{V}·C_{INT1}·R_{(T)}. Here, k_{V} is the ratio of the two reference voltages V_{DC2} and V_{DC}. This equation that can be used to trade-off factors k_{M}, k_{V}, and capacitance C_{INT1} to adjust the nominal integration time τ for a given R₀. Finally, the output voltage becomes: V_{OUT(T)}=(I_{REF}·τ)/C_{INT2}=k_{M}·k_{V}·I_{REF}(C_{INT1}/C_{INT2})·R_{(T)}=k_{M}·k_{V}·I_{REF}(C_{INT1}/C_{INT2})=R0(1+α·ΔT).

The output voltage scales linearly with temperature in accordance with the following equation: dV_{TEM(T)}/dT=k_{M}·k_{V}·I_{REF}(C_{INT1}/C_{INT2})·R0·α=K_{T}.

The slope constant, K_{T}, is a function of a ratio of capacitor values k_{C} for C_{INT1} and C_{INT2}, thereby reducing the sensitivity to process variations. Furthermore, the reference current I_{REF}, can be derived from an internally generated, stable bandgap reference voltage, and an internal, digitally trimmable resistor, or by using an external reference resistor in a controlled temperature environment. By doing so, one can set I_{REF} to be equal to V_{REF}/(k_{R}·R₀), thus: K_{T}=V_{REF}·((k_{M}·k_{V}·k_{C})·α. In some embodiments, k_{R} represents the ratio between the reference resistor (for converting V_{REF} into I_{REF}), and the nominal value of the measured resistive structure 230, R₀.

One can then write: I_{REF}=V_{REF}/R_{REF}, where R_{REF}=k_{R}·R₀.

Here, it should be understood that this equation provides many degrees of freedom, and the possibility to choose scaling factors k_{M}, k_{V}, k_{C}, and k_{R} so that the resistance change can be sensed with sufficient accuracy. Under sufficient accuracy, one can understand mV accuracy in the voltage domain of V_{OUT}, because ADCs can resolve input signals in the mV range.

FIG. 4B further illustrates switches Si and S2 connected across capacitors C_{INT1} and C_{INT2}. The switches S1 and S2 may be driven by a control signal RST (e.g., from the processor 110). During integration the switches Si and S2 are controlled to be open. During a reset period to reset the charge accumulated by the capacitors, the switches S1 and S2 may be controlled to be closed.

For purposes of illustration, consider an example where R₀=100 Ω, α=0.003/° C., C_{INT1}=10 pF, k_{M}=20, k_{V}=5, k_{C}=2, k_{R}=75, V_{REF}=1.25 V and V_{DC2}=V_{REF}, V_{DC}=250 mV, the integration time would amount to τ=100 ns with 0.1° C. accuracy (K_{T}=10 mV/° C., i.e., 1 mV/0.1° C.), which is a reasonable value for the integration time. Furthermore, different combinations of scaling factors may be selected, and other circuit topologies can be additionally implemented to, for example, improve the accuracy and bring the common mode voltage of V_{OUT} to what the ADC suits at best.

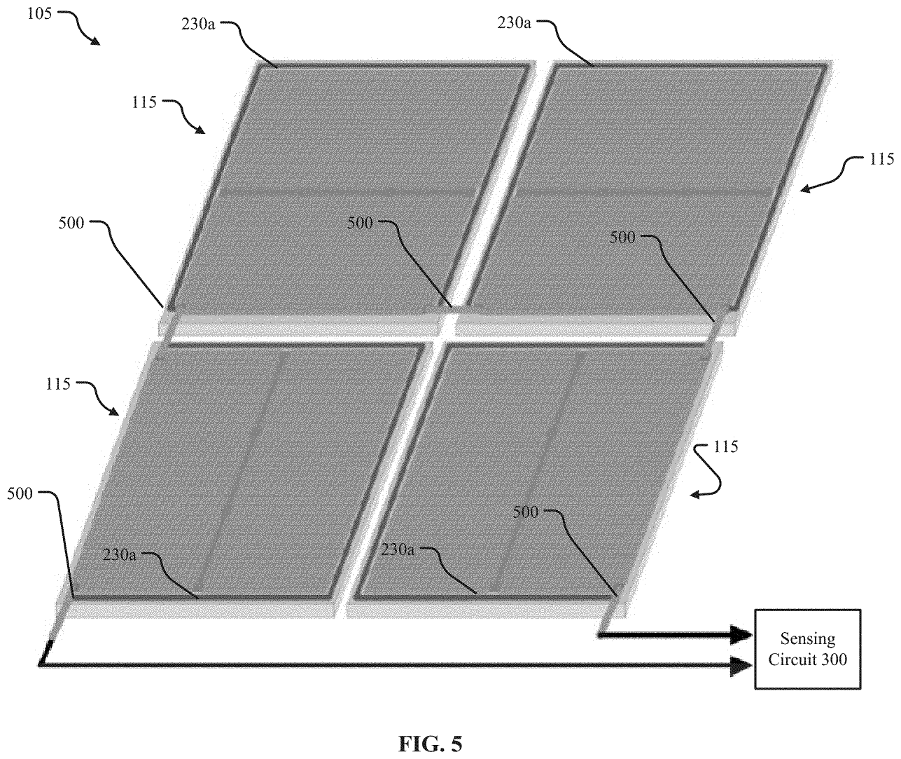

FIG. 5 illustrates a package according to at least one example embodiment. As shown in FIG. 5, the package 105 includes a plurality of substrates 115, each substrate 115 having a same or similar structure as described above and including a respective resistive structure 230a. As shown, the resistive structures 230a are connected in series across the substrates by wirings 500, which provides temperature monitoring for all of the substrates 115 in the package 105 via the sensing circuit 300. Here, it should be understood that more or fewer substrates 115 may be provided if desired. In FIG. 5, the wirings 500 may be formed on top surfaces of each substrate 115 and bonded to respective end points of each resistive structure 230a. Although not explicitly shown, it should be understood that the package 105 may further include support substrate 117 and resistive structures 230b and/or 230c as discussed above.

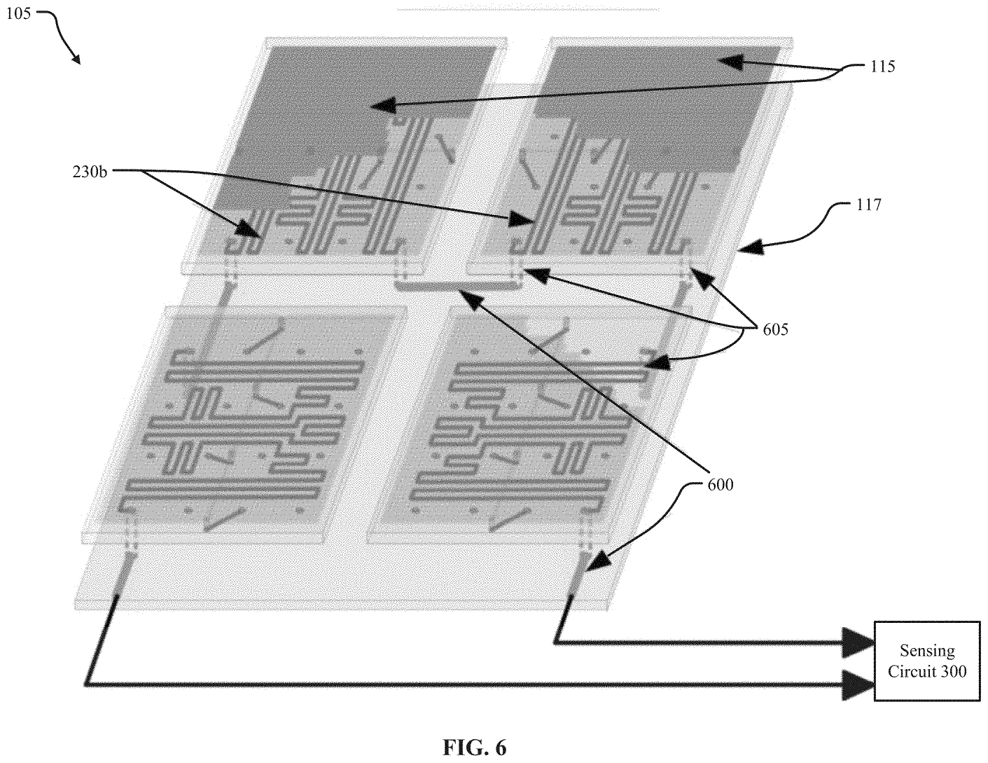

FIG. 6 illustrates a package according to at least one example embodiment. As shown in FIG. 6, the package 105 includes a plurality of substrates 115, each substrate 115 having a same or similar structure as described above and including a respective resistive structure 230b. As also shown, the resistive structures 230b are connected in series with one another using the wirings 600 formed on the support substrate 117 and solder bumps 605 to connect the resistive structures 230b to the wirings 600, which provides temperature monitoring for all of the substrates 115 in the package 105 via the sensing circuit 300. Here, it should be understood that some layers of the package 105 are removed for the sake of illustration and that more or fewer substrates 115 may be provided if desired. Although not explicitly shown, it should be understood that the package 105 may further include the resistive structures 230a and/or 230c as discussed above.

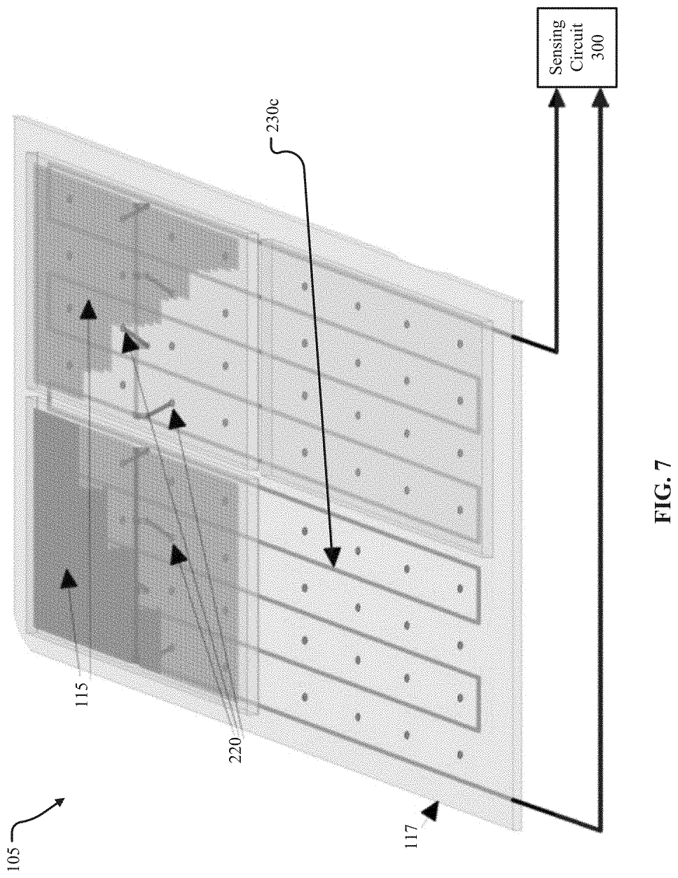

FIG. 7 illustrates a package according to at least one example embodiment. As shown in FIG. 7, the package 105 includes a plurality of substrates 115, each substrate 115 having a same or similar structure as described above. FIG. 7 further illustrates that the support substrate 117 includes a common resistive structure 230c for the substrates 115 connected to the sensing circuit 300. Here, it should be understood that some layers of the package 105 are removed for the sake of illustration and that more or fewer substrates 115 may be provided if desired. Although not explicitly shown, it should be understood that the package 105 may further include resistive structures 230a and/or 230b on substrates 115 as discussed above.

Although not explicitly shown, it should be understood that each substrate 115 in FIGS. 5-6 may be connected to its own sensing circuit 300 if desired, for example, if more localized temperature measurements of the package 105 are desired. In FIG. 7, the resistive structure 230c may include a plurality of resistive structures 230c, one for each substrate 115. In this case, each resistive structure 230c may be connected to a respective sensing circuit 300 to provide more localized temperature measurements.

It should be appreciated that inventive concepts are not limited to those example embodiments described above. For example, resistive structures may be formed in any desired pattern on and/or in proximity to a substrate 115. Each of the above described example embodiments can be combined with one another in any manner to increase the total resistance and to weigh which part of the system should be more dominant in the total temperature measurements.

At least one example embodiment measures the temperature of not only a substrate 115, but also the temperature of all of the system components of interest at once. For example, example embodiments measure the temperature of an SiPM die, a support PCB or other interposer, etc. Example embodiments also enable measuring the temperature of the system of several SiPM tiles (i.e., substrates 115) at once. This may be useful for a PET module carrying up to several tens of SiPM tiles. For that system, example embodiments provide a two-pad interface between the sensing circuit 300 and the SiPM tiles, a simplification compared to related art systems. Additionally, example embodiments may be easily implanted in any substrate where temperature measurement is desired.

In addition, it should be understood that specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring example embodiments.

While illustrative embodiments have been described in detail herein, it is to be understood that inventive concepts may be otherwise variously embodied and employed, and that the appended claims are intended to be construed to include such variations, except as limited by the prior art.

At least one example embodiment includes a semiconductor substrate including a first surface including an optical detection section that converts optical signals into electrical signals; a second surface opposite the first surface; one or more first contacts disposed on the first surface and/or second surface, wherein the one or more first contacts are electrically connected to the optical detection section to communicate the electrical signals from the optical detection section to another substrate; and a temperature sensing element that includes a resistive structure on at least the first surface or the second surface, the resistive structure having a resistance that varies with temperature.

According to at least one example embodiment, the semiconductor substrate further comprises one or more second contacts on the first surface and electrically connected to the optical detection section; and one or more vias formed through the semiconductor substrate and that electrically connect the one or more second contacts to the one or more first contacts to pass the electrical signals to the another substrate.

According to at least one example embodiment, the resistive structure is on the first surface at a periphery of the optical detection section.

According to at least one example embodiment, the resistive structure is at the periphery of the optical detection section around at least three sides of the optical detection section.

According to at least one example embodiment, the resistive structure is on the second surface and overlaps the optical detection section in a plan view.

According to at least one example embodiment, the resistive structure is sinuous and has line symmetry.

According to at least one example embodiment, the one or more first contacts includes a plurality of first contacts arranged in a desired pattern on the second surface, and the sinuous resistive structure winds between ones of the plurality of first contacts.

According to at least one example embodiment, the resistive structure includes a first portion and a second portion, the first portion being on the first surface at the periphery of the optical detection section, the second portion being on the second surface overlapping the optical detection section in a plan view.

According to at least one example embodiment, the semiconductor substrate further comprises a first via that connects wiring to the first portion and a second via that connects the second portion to the first portion.

According to at least one example embodiment, the first via and the second via are aligned with one another in a first direction.

At least one example embodiment includes a package including a first substrate including a plurality of optical elements that convert optical signals into electrical signals; and a first portion of a temperature sensing element on either a first surface of the substrate or a second surface of the substrate, the temperature sensing element having a metal resistor with a resistance that varies according to temperature. The package includes a second substrate attached to the first substrate and including a first set of terminals electrically connected to the temperature sensing element; and a second set of terminals electrically connected to the plurality of optical elements.

According to at least one example embodiment, the first substrate includes a second portion of the temperature sensing element on a second surface of the first substrate that is opposite the first surface.

According to at least one example embodiment, the second substrate includes a third portion of the temperature sensing element on a third surface of the second substrate.

According to at least one example embodiment, wherein the second surface of first substrate is attached to the third surface of the second substrate.

According to at least one example embodiment, the first portion of the temperature sensing element is at a periphery of the plurality of optical elements, and the second portion and the third portion of the temperature sensing element overlap the plurality of optical elements in a plan view.

According to at least one example embodiment, the second portion and the third portion of the temperature sensing element are sinuous and at least partially overlap one another.

According to at least one example embodiment, areas of the second portion and the third portion that overlap one another are physically separated by a space between the second surface and the third surface.

According to at least one example embodiment, the package includes a first circuit coupled to the first set of terminals and that senses the resistance of the temperature sensing element; and a second circuit coupled to the second set of terminals and that processes the electrical signals.

According to at least one example embodiment, the temperature sensing element includes metal.

At least one example embodiment includes a package including a first substrate including a plurality of optical elements that convert optical signals into electrical signals; and a first surface having a first portion of a temperature sensing element.

What is claimed is:

1. A semiconductor substrate, comprising:
a first surface including an optical detection section that converts optical signals into electrical signals;
a second surface opposite the first surface;
one or more first contacts disposed on the first surface and/or second surface, wherein the one or more first contacts are electrically connected to the optical detection section to communicate the electrical signals from the optical detection section to another substrate; and
a temperature sensing element that includes a resistive structure on at least the first surface or the second surface, the resistive structure having a resistance that varies with temperature.

2. The semiconductor substrate of claim 1, further comprising:
one or more second contacts on the first surface and electrically connected to the optical detection section; and
one or more vias formed through the semiconductor substrate and that electrically connect the one or more second contacts to the one or more first contacts to pass the electrical signals to the another substrate.

3. The semiconductor substrate of claim 1, wherein the resistive structure is on the first surface at a periphery of the optical detection section.

4. The semiconductor substrate of claim 3, wherein the resistive structure is at the periphery of the optical detection section around at least three sides of the optical detection section.

5. The semiconductor substrate of claim 1, wherein the resistive structure is on the second surface and overlaps the optical detection section in a plan view.

6. The semiconductor substrate of claim 5, wherein the resistive structure is sinuous and has line symmetry.

7. The semiconductor substrate of claim 6, wherein the one or more first contacts includes a plurality of first contacts arranged in a desired pattern on the second surface, and wherein the sinuous resistive structure winds between ones of the plurality of first contacts.

8. The semiconductor substrate of claim 3, wherein the resistive structure includes a first portion and a second portion, the first portion being on the first surface at the periphery of the optical detection section, the second portion being on the second surface overlapping the optical detection section in a plan view.

9. The semiconductor substrate of claim 8, further comprising:
a first via that connects wiring to the first portion; and
a second via that connects the second portion to the first portion.

10. The semiconductor substrate of claim 9, wherein the first via and the second via are aligned with one another in a first direction.

11. A package comprising:
a first substrate including:
a plurality of optical elements that convert optical signals into electrical signals; and
a first portion of a temperature sensing element on either a first surface of the substrate or a second surface of the substrate, the temperature sensing element having a metal resistor with a resistance that varies according to temperature; and
a second substrate attached to the first substrate and including:
a first set of terminals electrically connected to the temperature sensing element; and
a second set of terminals electrically connected to the plurality of optical elements.

12. The package of claim 11, wherein the first substrate includes a second portion of the temperature sensing element on a second surface of the first substrate that is opposite the first surface.

13. The package of claim 12, wherein the second substrate includes a third portion of the temperature sensing element on a third surface of the second substrate.

14. The package of claim 13, wherein the second surface of first substrate is attached to the third surface of the second substrate.

15. The package of claim 13, wherein the first portion of the temperature sensing element is at a periphery of the plurality of optical elements, wherein the second portion and the third portion of the temperature sensing element overlap the plurality of optical elements in a plan view.

16. The package of claim 15, wherein the second portion and the third portion of the temperature sensing element are sinuous and at least partially overlap one another.

17. The package of claim 16, wherein areas of the second portion and the third portion that overlap one another are physically separated by a space between the second surface and the third surface.

18. The package of claim 11, further comprising:
a first circuit coupled to the first set of terminals and that senses the resistance of the temperature sensing element; and
a second circuit coupled to the second set of terminals and that processes the electrical signals.

19. The package of claim 11, wherein the temperature sensing element includes metal.

20. A package comprising:
a first substrate including:
a plurality of optical elements that convert optical signals into electrical signals; and
a first surface having a first portion of a temperature sensing element; and
a second substrate including a second surface attached to the first surface and in electrical contact with a second portion of the temperature sensing element.
